(19) United States
(12) Patent Application Publication
(10) Pub. No.: US 2024/0142829 A1
(43) Pub. Date: May 2, 2024

(54) ARRAY SUBSTRATE AND MANUFACTURING METHOD THEREFOR, DISPLAY ASSEMBLY, AND DISPLAY DEVICE

(71) Applicants: BEIJING BOE OPTOELECTRONICS TECHNOLOGY CO., LTD., Beijing (CN); BOE TECHNOLOGY GROUP CO., LTD., Beijing (CN)

(72) Inventors: Jian WANG, Beijing (CN); Jinshuai DUAN, Beijing (CN); Xiaojuan WU, Beijing (CN); Hongliang YUAN, Beijing (CN); Zepeng SUN, Beijing (CN); Wei ZHAO, Beijing (CN); Yao BI, Beijing (CN); Jiaxing WANG, Beijing (CN); Xiaofeng YIN, Beijing (CN)

(73) Assignees: BEIJING BOE OPTOELECTRONICS TECHNOLOGY CO., LTD., Beijing (CN); BOE TECHNOLOGY GROUP CO., LTD., Beijing (CN)

(21) Appl. No.: 18/262,678

(22) PCT Filed: Jul. 5, 2022
(86) PCT No.: PCT/CN2022/103876

§ 371 Date: Jul. 24, 2023

(30) Foreign Application Priority Data
Jul. 20, 2021 (CN) 202110820513.7

(51) Int. Cl. G02F 1/1343; G02F 1/1362; H01L 27/12

(52) U.S. Cl. CPC G02F 1/134345; G02F 1/136209; G02F 1/136286; H01L 27/124

(57) ABSTRACT

An array substrate includes a first substrate; and a first electrode and a second electrode disposed on the first substrate and located in a sub-pixel region. At least one of the first electrode and the second electrode includes a plurality of electrode strips. Every two adjacent electrode strips in the first electrode and the second electrode have a slit therebetween. The slit includes a first end portion, a straight portion, and a second end portion connected in sequence. A bend is formed at a connection position of the first end portion and the straight portion, and the second end portion is formed by protruding from the straight portion. The straight portion includes a first edge and a second edge parallel to each other, and an average width of the first end portion in a direction perpendicular to the first edge is less than a width of the straight portion.

### CROSS-REFERENCE TO RELATED APPLICATIONS

This application is a national phase entry under 35 USC 371 of International Patent Application No. PCT/CN 2022/103876 filed on Jul. 5, 2022, which claims priority to Chinese Patent Application No. 202110820513.7, filed on Jul. 20, 2021, which are incorporated herein by reference in their entirety.

### TECHNICAL FIELD

The present disclosure relates to the field of display technologies, and in particular, to an array substrate and a manufacturing method therefor, a display assembly, and a display device.

### BACKGROUND

Liquid crystal display (LCD) devices have been widely popularized due to characteristics of small size, low power consumption, no radiation and high display resolution, and have gradually become mainstream products.

The liquid crystal display device can provide a driving electric field, and liquid crystal molecules in the liquid crystal display device are twisted due to an action of the driving electric field, thereby controlling a brightness of exit light of the liquid crystal display device.

### SUMMARY

In an aspect, an array substrate is provided. The array substrate has a plurality of sub-pixel regions. The array substrate includes a first substrate, and a first electrode and a second electrode that are disposed on the first substrate and located in a sub-pixel region. At least one of the first electrode and the second electrode includes a plurality of electrode strips. Every two adjacent electrode strips in the first electrode and the second electrode have a slit therebetween. The slit includes a first end portion, a straight portion and a second end portion connected in sequence. A bend is formed at a connection position of the first end portion and the straight portion, and the second end portion is formed by protruding from the straight portion in an extending direction of the straight portion. The straight portion includes a first edge and a second edge parallel to each other, and an average width of the first end portion in a direction perpendicular to the first edge is less than a width of the straight portion.

In some embodiments, a maximum width of the first end portion in the direction perpendicular to the first edge is less than the width of the straight portion.

In some embodiments, the first end portion includes a third edge and a fourth edge that are parallel to each other and respectively connected to the first edge and the second edge of the straight portion, and a fifth edge connected to the third edge and the fourth edge, and an included angle between the third edge and the first edge is an obtuse angle; and/or the second end portion includes a sixth edge and a seventh edge, the sixth edge and the first edge are located on a same straight line, and the seventh edge and the second edge are located on a same straight line.

In some embodiments, in the slit, the fifth edge of the first end portion is a convex curve or a convex broken line protruding in a direction away from the straight portion.

In some embodiments, the sub-pixel region is provided with a plurality of slits therein; straight portions of the plurality of slits are parallel to each other, and first end portions of the plurality of slits are located on a same side of respective straight portions connected to the first end portions.

In some embodiments, in the sub-pixel region, connection positions of the first end portions and the straight portions of the plurality of slits are on a straight line.

In some embodiments, in the sub-pixel region, the first end portions of the plurality of slits are bent toward a same side of the respective straight portions connected to the first end portions.

In some embodiments, the plurality of sub-pixel regions are arranged in a plurality of rows, and a row direction is parallel to an arrangement direction of the plurality of slits in the sub-pixel region. In two adjacent sub-pixel regions in a same row, first end portions of slits are bent toward a same side of respective straight portions connected to the first end portions of the slits in the two adjacent sub-pixel regions.

In some embodiments, the plurality of sub-pixel regions are arranged in a plurality of columns, and a column direction is perpendicular to an arrangement direction of the plurality of slits in the sub-pixel region. In two adjacent sub-pixel regions in a same column, first end portions of a plurality of slits in a sub-pixel region are respectively close to second end portions of a plurality of slits in another sub-pixel region.

In some embodiments, the plurality of sub-pixel regions are arranged in a plurality of columns, and a column direction is perpendicular to an arrangement direction of the plurality of slits in the sub-pixel region. In two adjacent sub-pixel regions in a same column, a straight line where first edges of a plurality of slits in a sub-pixel region are located is obtained by rotating the column direction clockwise by an acute angle, and a straight line where first edges of a plurality of slits in another sub-pixel region are located is obtained by rotating the column direction counterclockwise by an acute angle.

In some embodiments, the array substrate further includes a plurality of first signal lines and a plurality of second signal lines configured to define the plurality of sub-pixel regions. In the sub-pixel region, first edges of the straight portions of the plurality of slits are parallel to a portion of a first signal line for defining the sub-pixel region.

In some embodiments, the second signal lines are straight lines. The first signal line includes a plurality of first line segments and a plurality of second line segments that are alternately arranged, and an extending direction of a first line segment is different from an extending direction of a second line segment. Any first line segment and any second line segment adjacent to the any first line segment in the first signal line are axisymmetric about a second signal line disposed between the any first line segment and the any second line segment.

In some embodiments, the first signal lines are data lines, and the second signal lines are gate lines.

In another aspect, a display assembly is provided. The display assembly includes the array substrate in any one of the above embodiments, and further includes a black matrix disposed on a side of the first electrode and the second electrode in the array substrate away from the first substrate. An orthographic projection of the black matrix on the first substrate covers at least a portion of an orthographic projection, on the first substrate, of the first end portion included in the slit in the array substrate, and covers an orthographic projection, on the first substrate, of the second end portion included in the slit.

In some embodiments, the orthographic projection of the black matrix on the first substrate covers the orthographic projection, on the first substrate, of the first end portion included in the slit in the array substrate; and a portion of an edge of the black matrix is flush with a boundary line between a first end portion and a straight portion of each of at least one slit.

In some embodiments, a covering depth of the black matrix to the second end portion is no less than 2 μm.

In some embodiments, the display assembly further includes at least one spacer disposed on the side of the first electrode and the second electrode away from the first substrate. The orthographic projection of the black matrix on the first substrate covers an orthographic projection of a spacer in the at least one spacer on the first substrate.

In some embodiments, a distance between an orthographic projection of an edge of the black matrix on the first substrate and an edge of the orthographic projection of the spacer on the first substrate is not less than 4 μm.

In yet another aspect, a display device is provided. The display device includes the display assembly in any one of the above embodiments.

In yet another aspect, a manufacturing method of an array substrate is provided. The array substrate has a plurality of sub-pixel regions. The manufacturing method of the array substrate includes: forming a first electrode and a second electrode that are located in a sub-pixel region on a first substrate. At least one of the first electrode and the second electrode includes a plurality of electrode strips parallel to each other, and every two adjacent electrode strips in the first electrode and the second electrode have a slit therebetween. The slit includes a first end portion, a straight portion and a second end portion connected in sequence. A bend is formed at a connection position of the first end portion and the straight portion, and the second end portion is formed by protruding from the straight portion in an extending direction of the straight portion.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, and are not limitations on an actual size of a product, an actual process of a method, and an actual timing of a signal involved in the embodiments of the present disclosure.

FIG. 1 is a structural diagram of a pixel electrode or a common electrode in the related art;

FIG. 2 is a schematic diagram showing an arrangement state of liquid crystal molecules when pressed by an external force, in accordance with some embodiments;

FIG. 3 is a structural diagram of a liquid crystal display panel, in accordance with some embodiments;

FIG. 4 is a top view of the liquid crystal display panel shown in FIG. 3, in accordance with some embodiments;

FIG. 5 is a structural diagram of an array substrate, in accordance with some embodiments:

FIG. 6A is a structural diagram of a liquid crystal display panel, in accordance with some other embodiments;

FIG. 6B is a structural diagram of a liquid crystal display panel, in accordance with yet other embodiments;

FIG. 7 is a structural diagram of a COA substrate, in accordance with some embodiments;

FIG. 8 is a structural diagram of a liquid crystal display panel including the COA substrate, in accordance with some embodiments;

FIG. 9 is a structural diagram of a second electrode, in accordance with some embodiments;

FIG. 10 is a sectional view taken along the A-A′ direction in FIG. 9, in accordance with some embodiments;

FIG. 11 is a structural diagram of a first electrode and a second electrode, in accordance with some embodiments;

FIG. 12A is a sectional view taken along the B-B′ direction in FIG. 11, in accordance with some embodiments;

FIG. 12B is a sectional view taken along the B-B′ direction in FIG. 11, in accordance with some other embodiments;

FIG. 13 is a structural diagram of a first end portion and a straight portion in FIG. 9, in accordance with some embodiments;

FIG. 14 is a structural diagram of a second electrode, in accordance with some other embodiments;

FIG. 15 is a structural diagram of an array substrate, in accordance with some embodiments;

FIG. 16 is a structural diagram of a common electrode in the related art;

FIG. 17 is a structural diagram of an array substrate, spacers and black matrixes, in accordance with some embodiments;

FIG. 18 is a structural diagram of a liquid crystal display panel, in accordance with yet other embodiments;

FIG. 19 is a flow diagram of a manufacturing method of an array substrate, in accordance with some embodiments; and

FIG. 20 is a process flow diagram of a manufacturing method of an array substrate, in accordance with some embodiments.

### DETAILED DESCRIPTION

Technical solutions in some embodiments of the present disclosure will be described clearly and completely below with reference to the accompanying drawings. Obviously, the described embodiments are merely some but not all embodiments of the present disclosure. All other embodiments obtained by a person of ordinary skill in the art based on the embodiments of the present disclosure shall be included in the protection scope of the present disclosure.

In the description of the present disclosure, it will be understood that orientations or positional relationships indicated by terms “upper,” “lower,” “inner,” “outer,” etc., are based on orientations or positional relationships shown in the accompanying drawings, which are merely to facilitate and simplify the description of the present disclosure, but not to indicate or imply that the referred devices or elements must have a particular orientation, or must be constructed and operated in a particular orientation, and therefore are not to be construed as limiting the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “an example,” “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms such as “first” and “second” are only used for descriptive purposes, and are not to be construed as indicating or implying relative importance or implicitly indicating the number of indicated technical features. Thus, a feature defined with “first” or “second” may explicitly or implicitly include one or more of the features. In the description of the embodiments of the present disclosure, the term “a plurality of/the plurality of” means two or more unless otherwise specified.

In the description of some embodiments, the terms such as “coupled” and “connected” and extensions thereof may be used. For example, the term “connected” may be used in the description of some embodiments to indicate that two or more components are in direct physical or electrical contact with each other. For another example, the term “coupled” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the contents herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

As used herein, the term “if” is, optionally, construed to mean “When” or “in a case where” or “in response to determining” or “in response to detecting”, depending on the context. Similarly, the phrase “if it is determined” or “if [a stated condition or event] is detected” is, optionally, construed to mean “in a case where it is determined” or “in response to determining” or “in a case where [the stated condition or event] is detected” or “in response to detecting [the stated condition or event]”, depending on the context.

The use of the phrase “applicable to” or “configured to” herein means an open and inclusive expression, which does not exclude devices that are applicable to or configured to perform additional tasks or steps.

As used herein, the term such as “about,” “substantially” or “approximately” includes a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

As used herein, the term such as “parallel,” “perpendicular” or “equal” includes a stated condition and condition(s) similar to the stated condition. The similar condition(s) are within an acceptable range of deviation as determined by a person of ordinary skill in the art, considering measurement in question and errors associated with measurement of a particular quantity (i.e., limitations of a measurement system). For example, the term “parallel” includes “absolutely parallel” and “approximately parallel”, and for the phrase “approximately parallel”, an acceptable range of deviation may be, for example, within 5°. The term “perpendicular” includes “absolutely perpendicular” and “approximately perpendicular”, and for the phrase “approximately perpendicular”, an acceptable range of deviation may also be, for example, within 5°. The term “equal” includes “absolutely equal” and “approximately equal”, and for the phrase “approximately equal”, an acceptable range of deviation may be that, for example, a difference between two that are equal to each other is less than or equal to 5% of any one of the two.

Exemplary embodiments are described herein with reference to sectional views and/or plan views as idealized exemplary drawings. In the accompanying drawings, thicknesses of layers and sizes of regions are enlarged for clarity. Thus, variations in shape relative to the accompanying drawings due to, for example, manufacturing techniques and/or tolerances may be envisaged. Therefore, the exemplary embodiments should not be construed to be limited to the shapes of regions shown herein, but to include deviations in shape due to, for example, manufacturing. For example, an etched region shown in a rectangular shape generally has a curved feature. Therefore, the regions shown in the accompanying drawings are schematic in nature, and their shapes are not intended to show actual shapes of the regions in a device, and are not intended to limit the scope of the exemplary embodiments.

In a liquid crystal display device, liquid crystal molecules are twisted generally through a driving electric field formed by a pixel electrode and a common electrode. In order to further improve a display effect of the liquid crystal display device to achieve higher liquid crystal working efficiency and light transmission efficiency, an advanced-super dimensional switching (AD-SDS) technology is widely used in the liquid crystal display device. Generally, one of the pixel electrode and the common electrode in the AD-SDS liquid crystal display device has slits. For example, the pixel electrode has the slits. In this case, in the AD-SDS liquid crystal display device, a multi-dimensional electric field is formed through parallel electric fields generated by edges of the pixel electrode in the same plane and vertical electric fields generated between the pixel electrode and the common electrode, so that all oriented liquid crystal molecules in the pixel electrode (i.e., directly above the slits of the pixel electrode) and directly above the pixel electrode in the liquid crystal layer are capable of being rotated, thereby improving the liquid crystal working efficiency of the planar orientation system and increasing the light transmission efficiency. A relative position of the common electrode and the pixel electrode is not excessively limited, and the upper and lower positions of the common electrode and the pixel electrode may be changed. The application of advanced-super dimensional switching technology may improve the image quality of the liquid crystal display device, and has advantages of high transmittance, wide viewing angle, high aperture ratio, low color difference, short response time, and no push mura.

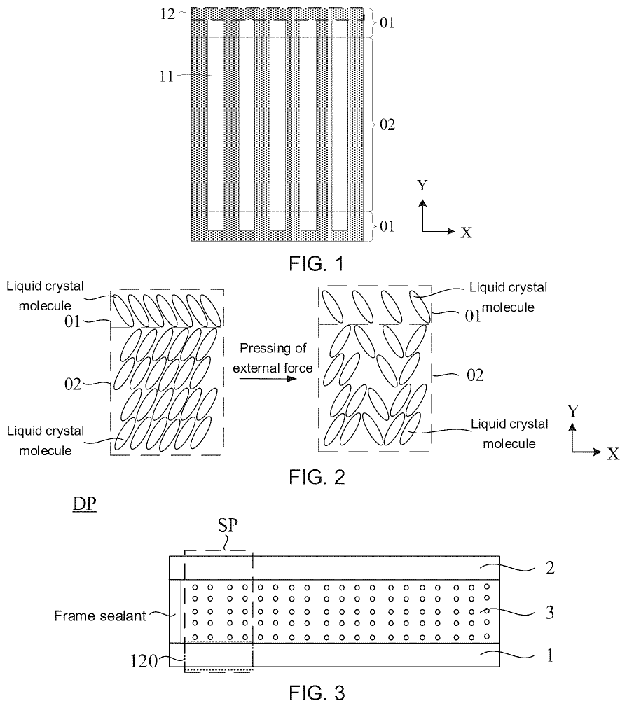

For example, when the pixel electrode of the liquid crystal display device is as shown in FIG. 1, the pixel electrode has end regions 01 and a middle region 02. Vertical electrode strips 11 located in the middle region 02 generate electric fields in an X direction (i.e., a direction perpendicular to an extending direction of the vertical electrode strip), and the liquid crystal molecules are rotated due to an action of the electric fields in the X direction, thereby allowing light to pass through. However, lateral connection portions 12 respectively located in the end regions 01 generate an electric field in a Y direction (i.e., a direction perpendicular to the X direction). Referring to FIG. 2, due to the existence of the electric field in the Y direction in the end region 01, liquid crystal molecules distributed in the end region 01 have an abnormal arrangement different from that of liquid crystal molecules distributed in the middle region 02, which results in black domain lines (i.e., Trace mura). When the liquid crystal display device is subjected to an external force, the liquid crystal molecules that are abnormally arranged and distributed in the end region 01 are pushed to the middle region 02 due to an action of the external force, so that the arrangement of the liquid crystal molecules distributed in the middle region 02 are affected, and a distribution range of the liquid crystal molecules that are abnormally arranged is increased, which aggravates the Trace mura. When the external force is removed, the liquid crystal molecules need to return to an initial arrangement state due to the action of the electric field in the X direction. However, due to hindrance of the electric field in the Y direction, the liquid crystal molecules return to the initial arrangement state slowly, or cannot return to the initial arrangement state, thereby adversely affecting the display effect.

In order to solve the above problems, some embodiments of the present disclosure provide a display device. The display device is configured to display image(s), which may be, for example, static image(s) or dynamic image(s). For example, the display device may be a liquid crystal display panel, or a product including a liquid crystal display panel and driving circuits (the driving circuits are coupled to the liquid crystal display panel and configured to drive the liquid crystal display panel to display image(s)). Since liquid crystal molecules only modulate light, and cannot emit light by themselves, in order to realize image display, for example, the product may further include a backlight module disposed on a back of the liquid crystal display panel (i.e., a side of the liquid crystal display panel facing away from a display surface thereof). The backlight module is configured to provide backlight to the liquid crystal display panel. The type of the backlight module is not excessively limited, and may be, for example, a side-type backlight module or a direct-type backlight module.

For example, the product may be a display, a television, a billboard, a digital photo frame, a laser printer with a display function, a telephone, a mobile phone, a personal digital assistant (PDA), a digital camera, a camcorder, a viewfinder, a navigator, a vehicle display device, a splicing display device, a household appliance, an information inquiry device (e.g., a business inquiry device of an e-government department, a bank, a hospital or an electric power department), or a monitor.

For example, the liquid crystal display panel may be an ADS (AD-SDS) liquid crystal display panel, or an in-plane switch (IPS) liquid crystal display panel.

In some embodiments, referring to FIG. 3, the liquid crystal display panel DP may include an array substrate 1, an opposite substrate 2, and a liquid crystal layer 3 encapsulated between the array substrate 1 and the opposite substrate 2. The array substrate 1 and the opposite substrate 2 are bonded by a frame sealant to form a closed space, and the liquid crystal layer 3 is sealed in the closed space. The frame sealant needs to have a high adhesive strength and a good bonding strength. The frame sealant is generally made of one of silicone (also referred to as silicone resin), light-curable resin (also referred to as UV-curable resin), epoxy resin and phenolic resin, or a mixture thereof.

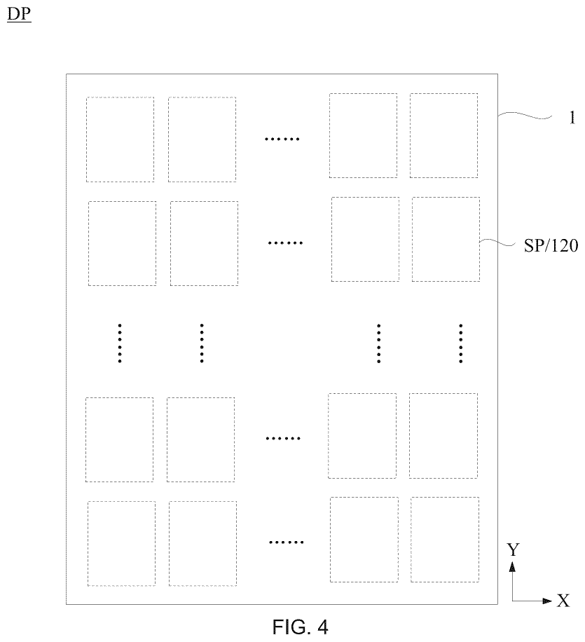

Referring to FIG. 4, the liquid crystal display panel DP has a plurality of sub-pixel regions SP, which may include sub-pixel regions of three primary colors, such as red sub-pixel regions, green sub-pixel regions and blue sub-pixel regions, and sub-pixel regions SP of different colors have exit light of different colors. The plurality of sub-pixel regions SP here may be all of or some of the sub-pixel regions SP of the liquid crystal display panel DP. The plurality of sub-pixel regions SP may be arranged in an array, or may have other arrangements, which is not excessively limited. The liquid crystal display panel DP is configured to control an electric field strength in a sub-pixel region SP (e.g., in each of the plurality of sub-pixel regions) to adjust an arrangement state of liquid crystal molecules in this sub-pixel region SP in the liquid crystal layer under the corresponding electric field strength, thereby adjusting a light transmittance of the backlight passing through this sub-pixel region SP. That is, a brightness of exit light of this sub-pixel region SP is controlled to display desired image(s).

Referring to FIGS. 3 and 4 again, the array substrate 1 is configured to apply an electric field to liquid crystal molecules in a sub-pixel region SP (e.g., in each of the plurality of sub-pixel regions) in the liquid crystal layer. The array substrate 1 has a plurality of sub-pixel regions 120 respectively corresponding to the plurality of sub-pixel regions SP of the liquid crystal display panel DP.

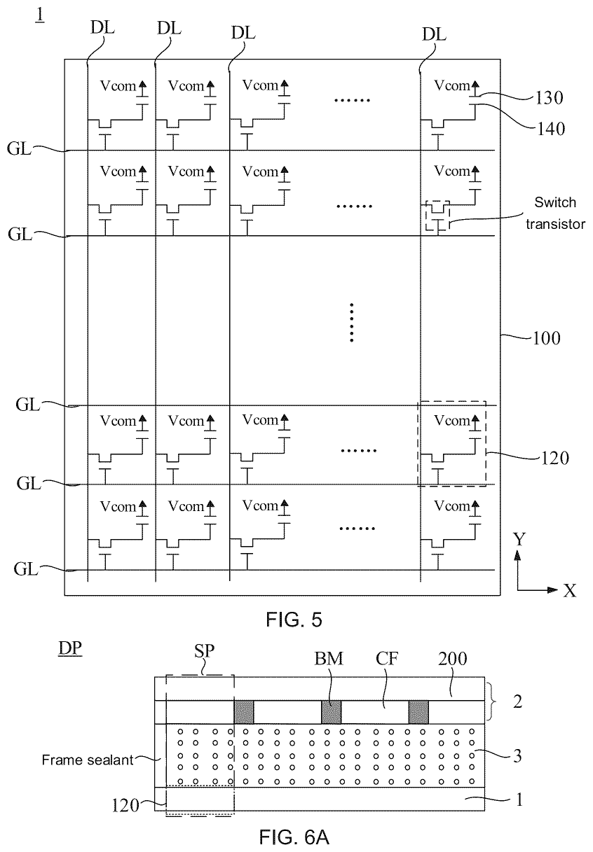

Referring to FIG. 5, the array substrate 1 includes a first substrate 100. The first substrate 100 may be a rigid base substrate, and the rigid base substrate may be, for example, a glass base substrate or a polymethyl methacrylate (PMMA) base substrate. For another example, the first substrate 100 may be a flexible base substrate. The flexible base substrate may be, for example, a polyethylene terephthalate (PET) base substrate, a polyethylene naphthalate two formic acid glycol ester (PEN) base substrate, a polyimide (PI) base substrate, or an ultra-thin glass.

Referring to FIG. 5, the array substrate 1 further includes a first electrode 130 and a second electrode 140 that are disposed on the first substrate 100 and located in a sub-pixel region 120 (e.g., located in each of the plurality of sub-pixel regions of the array substrate 1). The first electrode 130 and the second electrode 140 each may be made of a transparent conductive material, such as indium tin oxide (ITO), indium zinc oxide (IZO) or indium gallium zinc oxide (IGZO). The array substrate 1 may further include at least one gate line GL (e.g., a plurality of gate lines GL), at least one data line DL (e.g., a plurality of data lines DL) and a switch transistor (e.g., thin film transistor, TFT) corresponding to a sub-pixel region 120. The first electrode 130 and the second electrode 140 in the sub-pixel region 120 are insulated from each other, and one of the first electrode 130 and the second electrode 140 is coupled to the switch transistor, and is referred to as a pixel electrode, and another one of the first electrode 130 and the second electrode 140 is a common electrode. Common electrodes in the plurality of sub-pixel regions 120 may be coupled to each other, and may be configured to be applied with a common voltage Vcom. The switch transistor is coupled to a gate line GL and a data line DL, and is configured to apply a data voltage transmitted from the data line DL to the pixel electrode in response to a scan signal transmitted from the gate line GL. A data voltage applied to a pixel electrode in a different sub-pixel region 120 may be separately controlled, so that an electric field formed by the pixel electrode and the common electrode in each sub-pixel region 120 may be separately controlled.

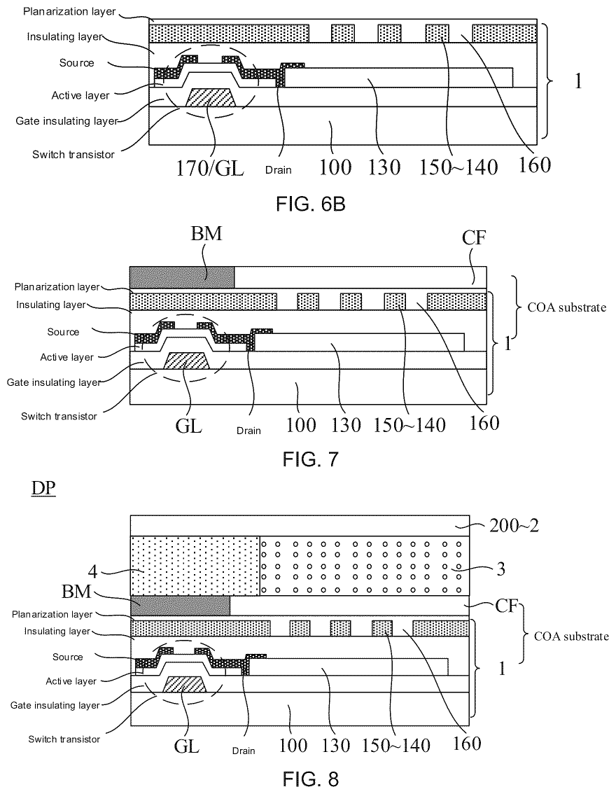

Referring to FIG. 6A, the opposite substrate 2 further includes a second substrate 200. The second substrate 200 is used for carrying film layers in the opposite substrate 2. Optional materials for the second substrate 200 are the same as those for the first substrate 100, and will not be repeated here.

In some embodiments, referring to FIG. 6A, the opposite substrate 2 may further include a color filter film CF (also referred to as a color filter or a color filter layer) and black matrixes BM that are all disposed on the second substrate 200. The color filter film CF is an optical filter that exhibits colors, which is able to filter out light waves of other bands and only transmit light waves of a specific band, so that light passing through the color filter film CF exhibits specific colors. The color filter film CF may include filter patterns of a plurality of colors. For example, the color filter film CF may include red filter patterns, green filter patterns and blue filter patterns. The red light filter pattern only allows red light to pass therethrough, the green light filter pattern only allows green light to pass therethrough, and the blue light filter pattern only allows blue light to pass therethrough. Each filter patter corresponds to a sub-pixel region 120, and the color of the sub-pixel region 120 is determined by a color of light allowed to pass through the filter pattern corresponding to this sub-pixel region. The black matrix BM is used for spacing filter patterns of different colors to avoid color mixing. Moreover, the black matrix BM further functions to shield light. The black matrix BM may be made of a black resin including at least one of carbon particles, titanium particles and pigments, which are coated with an insulating material.

Accordingly, FIG. 6B illustrates a structure of a sub-pixel region included in the array substrate 1 in FIG. 6A. Referring to FIG. 6B, the first electrode 130 included in the array substrate 1 is coupled to the switch transistor, and is used as the pixel electrode. The second electrode 140 may be applied with the common voltage Vcom, and is used as the common electrode. A planarization layer is disposed on a side of the second electrode 140 away from the first substrate 100.

In some other embodiments, referring to FIG. 7, the color filter film CF may be disposed on the array substrate 1 (e.g., on the planarization layer) to constitute a color filter on array (COA) substrate. In this case, the black matrixes BM may also be disposed on the array substrate 1. For example, the black matrixes BM are disposed on a side of the first electrode 130 and the second electrode 140 away from the first substrate 100, and are carried by the first substrate 100. Moreover, the color filter film CF is further disposed on the side of the first electrode 130 and the second electrode 140 away from the first substrate 100, and a filter pattern in the color filter film CF corresponds to a sub-pixel region.

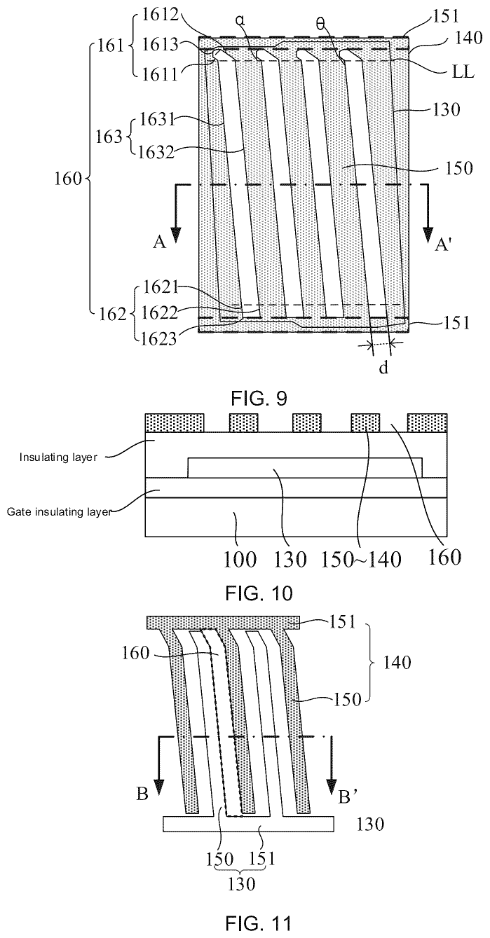

Accordingly, referring to FIG. 8, in the liquid crystal display panel DP including the COA substrate, the opposite substrate 2 may include the second substrate 200, and in this case, the color filter film CF and the black matrixes BM are not disposed on the second substrate 200.

Embodiments of the present disclosure provide a display assembly. The display assembly includes the array substrate and the black matrixes. For example, the black matrixes are disposed on the opposite substrate, but not on the array substrate. In this case, the display assembly may be the liquid crystal display panel DP shown in FIG. 6A. For another example, the black matrixes may be disposed on the array substrate. In this case, the display assembly may be the COA substrate shown in FIG. 7, or the liquid crystal display panel DP including the COA substrate shown in FIG. 8.

Below, referring to FIGS. 9 to 14, the first electrode 130 and the second electrode 140 in the array substrate 1 above will be described in detail.

At least one (e.g., the second electrode 140) of the first electrode 130 and the second electrode 140 includes a plurality of electrode strips (also referred to as sub-electrodes) 150, and the electrode strips 150 in the same electrode are coupled to each other through connection portion(s) 151. In the first electrode 130 and the second electrode 140, every two adjacent electrode strips 150 have a slit 160 therebetween.

A relative position of the first electrode 130 and the second electrode 140 is not excessively limited in these embodiments, and the first electrode 130 and the second electrode 140 may be arranged in a same layer or in different layers.

In some embodiments, referring to FIGS. 9 to 12A, the first electrode 130 and the second electrode 140 are arranged in different layers, which may be that the first electrode 130 is closer to the first substrate 100 than the second electrode 140, or may be that the second electrode 140 is closer to the first substrate 100 than the first electrode 130. The first electrode 130 and the second electrode 140 are spaced apart through an insulating layer (also referred to as a passivation layer or a protective layer, which may be made of an inorganic insulating material such as silicon oxide or silicon nitride). The at least one of the first electrode 130 and the second electrode 140 includes the plurality of electrode strips 150 spaced apart from each other, so that a horizontal electric field may be formed.

For example, in a case where the liquid crystal display panel is the ADS liquid crystal display panel, referring to FIGS. 9 and 10, the first electrode 130 is closer to the first substrate 100 than the second electrode 140. The first electrode 130 is a plate electrode (also referred to as a planar electrode), and the second electrode 140 includes the plurality of electrode strips 150. In the second electrode 140, the slit 160 is formed between two adjacent electrode strips 150, and the electrode strips 150 may be coupled to each other through two connection portions 151 respectively located on two ends of each electrode strip 150, or of course, may be coupled to each other only through a connection portion 151 located on an end of each electrode strip 150, so as to form a comb-like electrode structure.

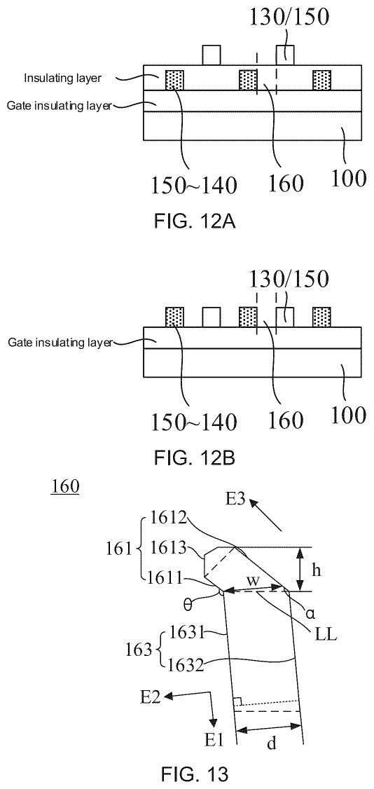

For another example, referring to FIGS. 11 and 12A, in a case where the liquid crystal display panel is the IPS liquid crystal display panel, the first electrode 130 and the second electrode 140 each include the plurality of electrode strips 150. The electrode strips 150 in the first electrode 130 and the electrode strips 150 in the second electrode 140 are arranged alternately. For the convenience of description, the electrode strips 150 in the first electrode 130 are referred to as first electrode strips, and the electrode strips 150 in the second electrode 140 are referred to as second electrode strips. The slit 160 is formed between a first electrode strip and a second electrode strip that are adjacent to each other. In addition, the electrode strips 150 in the same electrode are coupled to each other through at least one connection portion 151. For example, the first electrode strips in the first electrode 130 may be coupled through a connection portion 151 located on an end of each first electrode strip. Alternatively, similar to the structure of the second electrode 140 in FIG. 9, the first electrode strips in the first electrode 130 may be coupled through two connection portions respectively located on two ends of each first electrode strip.

In some other embodiments, referring to FIGS. 11 and 12B, the liquid crystal display panel is still the IPS liquid crystal display panel, and the first electrode 130 and the second electrode 140 may be arranged in the same layer. That is, the first electrode 130 and the second electrode 140 are located on an upper surface (i.e., a surface away from the substrate 100) of the same layer. For example, the first electrode 130 and the second electrode 140 are located on an upper surface of a gate insulating layer. For example, the first electrode 130 and the second electrode 140 may be directly formed by one patterning process.

For the sake of clarity, in the embodiments of the present disclosure, referring to FIGS. 9 and 10, solutions of the present disclosure will be explained in an example where the first electrode 130 is the plate electrode, the second electrode 140 includes the plurality of electrode strips 150 that are coupled to each other through at least one connection portion 151, the first electrode 130 and the second electrode 140 are arranged in different layers, and the first electrode 130 is closer to the first substrate 100 than the second electrode 140.

Referring to FIG. 9, at least one slit 160 (e.g., each slit 16) in the second electrode 140 includes a first end portion 161, a straight portion 163 and a second end portion 162 connected in sequence. A bend is formed at a connection position of the first end portion 161 and the straight portion 163.

FIG. 13 is an enlarged view of the bending angle of the slit 160 in FIG. 9. Referring to FIGS. 9 and 13 again, for the slit 160 (e.g., each slit 160), the bend is formed at the connection position of the first end portion 161 and the straight portion 163, and a shape of the bend is determined by a bending direction and bending angle(s) a of the first end portion 161. Each first end portion 161 may have only a single bending direction, but may have more than one bending angle α (e.g., two bending angles α). The first end portion 161 includes a third edge 1611 and a fourth edge 1612 that are respectively connected to a first edge 1631 and a second edge 1632 of the straight portion, and the bending direction of the first end portion 161 is determined by extending directions of the third edge 1611 and the fourth edge 1612 of the first end portion 161. Compared with an extending direction E1 of the straight portion 163, if the extending directions of the third edge 1611 and the fourth edge 1612 correspond to the same rotation direction, the first end portion 161 has a single bending direction; otherwise, the first end portion 161 has two bending directions. The extending direction of the third edge 1611 of the first end portion 161 may be obtained by rotating an extending direction of the first edge 1631 of the straight portion 163 connected thereto by an acute angle clockwise or counterclockwise. Similarly, an extending direction of the fourth edge 1612 of the first end portion 161 may be obtained by rotating an extending direction of the second edge 1632 of the straight portion 163 connected thereto by an acute angle clockwise or counterclockwise. For example, in FIG. 13, the extending direction of the third edge 1611 may be obtained by rotating the extending direction of the first edge 1631 connected thereto by an acute angle counterclockwise. In this way, an included angle θ between the third edge 1611 and the first edge 1631 is an obtuse angle. Accordingly, the extending direction of the fourth edge 1612 may be obtained by rotating the extending direction of the second edge 1632 connected thereto by an acute angle counterclockwise, and in this case, the bending direction of the first end portion 161 is a counterclockwise direction.

The bending angle α of the first end portion 161 is an included angle between a straight line LL where the connection position of the first end portion 161 and the straight portion 163 is located (i.e., a straight line where a line connecting an intersection point of the third edge 1611 and the first edge 1631 and an intersection point of the fourth edge 1612 and the second edge 1632 is located) and the third edge 1611 of the first end portion 161, or is an included angle between the straight line LL where the connection position of the first end portion 161 and the straight portion 163 is located and the fourth edge 1612 of the first end portion 161. FIG. 13 illustrates the bending angle α corresponding to the fourth edge 1612. The two edges (i.e., the third edge 1611 and the fourth edge 1612) of the first end portion 161 connected to the straight portion 163 may be parallel to each other, or may not be parallel to each other. In a case where the third edge 1611 and the fourth edge 1612 of the first end portion 161 are parallel to each other, the bend of the slit 160 has only a single bending angle α. In a case where the third edge 1611 and the fourth edge 1612 of the first end portion 161 are not parallel to each other, the bend of the slit 160 has two bending angles α, and the bending angles α are acute angles. For example, in FIG. 13, the third edge 1611 and the fourth edge 1612 of the first end portion 161 are parallel to each other, and therefore, the bend of the slit 160 has only the single bending angle α. The bending angle α is in a range of 30° to 60°, inclusive, and the bending angle α is 35°, 40°, 45° or 50°.

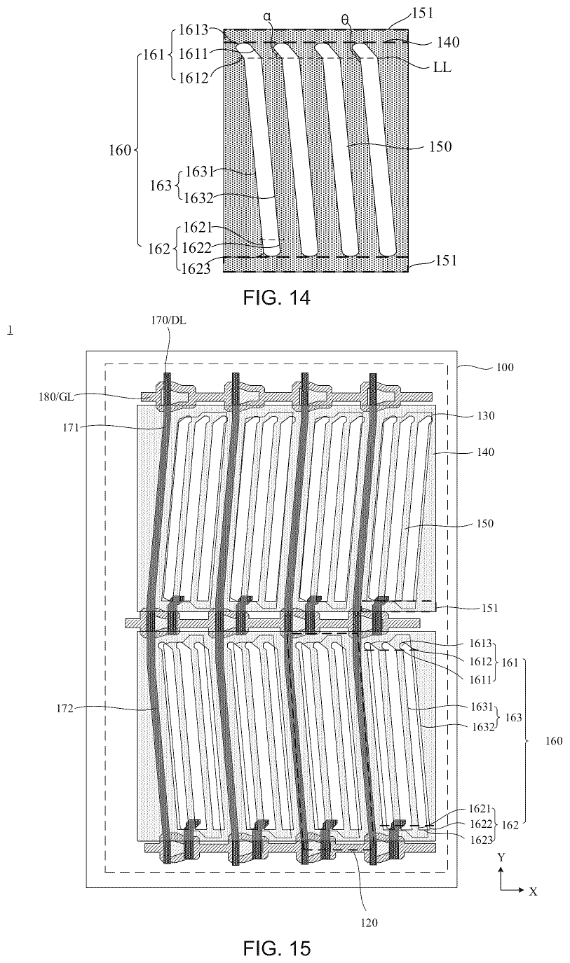

In addition, the first end portion 161 of the slit 160 may further include a fifth edge 1613 connected to the third edge 1611 and the fourth edge 1612. A specific shape of the fifth edge 1613 is not excessively limited, and may be a broken line, a straight line, or an arc. For example, for the slit 160 (e.g., each slit 160), the fifth edge 1613 of the first end portion 161 is a convex curve or a convex broken line protruding in a direction E3 away from the straight portion. If a plane curve is located on the same side of a tangent line at any point of the plane curve, the plane curve is the convex curve. Similarly, a plurality of line segments are connected to form the broken line, and the broken line is located on the same side of any line segment. Then, the broken line is the convex broken line. For example, referring to FIG. 13, the fifth edge 1613 is the convex broken line formed by connecting a plurality of (e.g., at least three) line segments. For another example, FIG. 14 illustrates another shape of the slit in the second electrode. Referring to FIG. 14, in the slit 160, the shapes of the third edge 1611 and the fourth edge 1612 of the first end portion 161 may refer to the descriptions with respect to FIGS. 9 and 13. The shape of the fifth edge 1613 of the first end portion 161 is a convex arc. As an example, a line connecting an intersection point of the fifth edge 1613 and the third edge 1611 and an intersection point of the fifth edge 1613 and the fourth edge 1612 may be perpendicular to the third edge 1611, or may be parallel to the straight line LL where the connection position of the first end portion 161 and the straight portion 163 is located, which is not limited in these embodiments.

In some embodiments, referring to FIG. 9 again, the second end portion 162 of the slit 160 is formed by protruding from the straight portion 163 in the extending direction thereof, which means that the second end portion 162 does not exceed a region defined by a straight line where the first edge 1631 is located and a straight line where the second edge 1632 is located. A specific shape of the second end portion 162 is not excessively limited in these embodiments. The second end portion 162 may include a sixth edge 1621 and a seventh edge 1622. The sixth edge 1621 is connected to the first edge 1631, and the seventh edge 1622 is connected to the second edge 1632. For example, the sixth edge 1621 and the first edge 1631 are located on the same straight line, and the seventh edge 1622 and the second edge 1632 are located on the same straight line. The sixth edge 1621 and the seventh edge 1622 are parallel to each other. For example, in a case where the sixth edge 1621 and the seventh edge 1622 are not connected, the second end portion 162 may further include an eighth edge 1623 connected to the sixth edge 1621 and the seventh edge 1622. Similar to the fifth edge 1613, a specific shape of the eighth edge 1623 is not excessively limited, and may be a broken line, a straight line, or an arc. For example, referring to FIG. 9, the shape of the eighth edge 1623 is the straight line, and in this case, the shape of the second end portion 162 protruding in the extending direction of the straight portion 163 is a parallelogram. For another example, referring to FIG. 14, the shape of the eighth edge 1623 is a convex arc.

In some embodiments, the second end portion 162 is formed by protruding from the straight portion 163 in the extending direction thereof. The straight portion 163 includes the first edge 1631 and the second edge 1632 parallel to each other, and an average width of the first end portion 161 in a direction E2 perpendicular to the first edge 1631 is less than a width d of the straight portion 163.

Referring to FIGS. 9 and 13, the width d of the straight portion 163 is a distance between the first edge 1631 and the second edge 1632 of the straight portion 163. Since the first edge 1631 and the second edge 1632 of the straight portion 163 are parallel to each other, the distance between the first edge 1631 and the second edge 1632 is equal everywhere. In a case where the first edge 1631 and the second edge 1632 of the straight portion 163 are not completely parallel, i.e., in a case where an included angle between the straight line where the first edge 1631 is located and the straight line where the second edge 1632 is located is not greater than 5°, the distance between the first edge 1631 and the second edge 1632 is not equal everywhere. In this case, the width d of the straight portion 163 may be an average value of a maximum distance and a minimum distance each between the first edge 1631 and the second edge 1632 of the straight portion 163, or may be the maximum distance or the minimum distance.

For example, an image of the slit 160 (i.e., an image of the first end portion 161) may be acquired by an image acquisition tool (also referred to as an image sensor). For example, a complementary metal-oxide semiconductor (CMOS) camera, a charge coupled device (CCD) camera, or other industrial cameras may be used to acquire the image of the slit 160. Then, an auxiliary tool such as Auto Cad, Matlab or OpenCV is used to measure a plurality of width values (which may be at least three width values, e.g., 10, 15 or 20 width values) of the first end portion 161 in the direction perpendicular to the first edge 1631, and then an average value of the obtained plurality of width values is calculated to finally obtain the average width of the first end portion 161 in the direction perpendicular to the first edge 1631. Measurement positions corresponding to these width values may be arranged at equal intervals in a direction parallel to the first edge 1631.

The average width of the first end portion 161 in the direction perpendicular to the first edge 1631 is less than the width of the straight portion 163. For example, the average width of the first end portion 161 in the direction perpendicular to the first edge 1631 is in a range of 1.7 μm to 3 μm, inclusive, and the width of the straight portion 163 is approximately 2 to 2.5 times the average width of the first end portion 161 in the direction perpendicular to the first edge 1631. For example, the average width of the first end portion 161 in the direction perpendicular to the first edge 1631 is 1.75 μm. The width of the straight portion 163 is 2 to 2.5 times the average width of the first end portion 161 in the direction perpendicular to the first edge, e.g., 2.4 times, and in this case, the width of the straight portion 163 is 4.2 μm. For another example, the average width of the first end portion 161 in the direction perpendicular to the first edge 1631 is 2.55 μm. The width of the straight portion 163 is 2 to 2.5 times the average width of the first end portion 161 perpendicular to the first edge, e.g., 2 times, and in this case, the width of the straight portion 163 is 5.1 μm.

An electric field formed at a position corresponding to the straight portion 163 is the horizontal electric field for rotating the liquid crystal molecules to realize the image display, and a direction of the horizontal electric field is perpendicular to the first edge 1631. Since the first edge 1631 is parallel to the second edge 1632, the direction of the horizontal electric field is also perpendicular to the second edge 1632. The average width of the first end portion 161 in the direction perpendicular to the first edge 1631 is less than the width of the straight portion 163. That is, a distance, in the direction perpendicular to the first edge 1631, between electrode strips 150 respectively disposed on two sides of the first end portion 161 is less than a distance, in the direction perpendicular to the first edge 1631, between electrode strips 150 respectively disposed on two sides of the straight portion 163, so that in the direction perpendicular to the first edge 1631, a strength of a horizontal electric field at a position corresponding to the first end portion 161 is greater than a strength of the horizontal electric field at the position corresponding to the straight portion 163, which is equivalent to increasing the strength of the horizontal electric field at the position corresponding to the first end portion 161. Thus, an effect of the horizontal electric field at the position corresponding to the first end portion 161 on an arrangement state of liquid crystal molecules is able to be enhanced, thereby reducing an influence of an electric field in other direction at the position corresponding to the first end portion 161 on the arrangement state of the liquid crystal molecules, so that the arrangement state of the liquid crystal molecules is closer to an arrangement state of liquid crystal molecules at the position corresponding to the straight portion 163, so as to achieve an effect of reducing Trace mura. Moreover, after pressing of an external force, the stronger horizontal electric field at the position corresponding to the first end portion 161 generated by the above arrangements is further able to make the liquid crystal molecules return to an initial arrangement state quickly, thereby shortening an existence duration of the Trace mura caused by the pressing of the external force, which is conducive to the improvement of the display effect.

In addition, a region except the straight portions 163 may be covered by the black matrix to avoid adverse effects of visualization of the Trace mura on the display effect. The larger the distribution range of the Trace mura, the larger the coverage of the black matrix. However, the larger the coverage of the black matrix, the smaller the aperture ratio of the sub-pixel in the liquid crystal display panel, which also adversely affects the display effect. The arrangement of the first electrode 130 and the second electrode 140 in the embodiments of the present disclosure is able to achieve the effect of reducing the Trace mura, which is correspondingly conducive to reducing the distribution range of the Trace mura. Thus, when the Trace mura is covered by the black matrix, the coverage of the black matrix is able to be reduced, and the aperture ratio is able to be increased, thereby improving the display effect. Moreover, the second end portion 162 is formed by protruding from the straight portion 163 in the extending direction thereof, and no bend is formed at a connection position of the second end portion 162 and the straight portion 163, so that a direction of an electric field at a position corresponding to a portion of the second end portion 162 is the same as the direction of the electric field at the position corresponding to the straight portion 163, and the arrangement state of the liquid crystal molecules is also the same. Equivalently, in addition to the position corresponding to the straight portion 163, the display effect may also be achieved at the position corresponding to the portion of the second end portion 162, so that an area of an effective display region of the sub-pixel region 120 is able to be increased, which is conducive to the improvement of the display effect.

For example, referring to FIG. 13, a maximum width w of the first end portion 161 in the direction perpendicular to the first edge is less than the width d of the straight portion 163. That is, any width of the first end portion 161 in the direction perpendicular to the first edge is less than the width d of the straight portion 163. Thus, the average width of the first end portion 161 in the direction perpendicular to the first edge is ensured to be less than the width of the straight portion 163, so that the horizontal electric field is further enhanced at a position corresponding to the any width of the first end portion 161, which is able to better reduce the Trace mura, and is conducive to increasing the aperture ratio and shortening the existence duration of the Trace mura caused by the pressing of the external force, thereby improving the display effect.

For example, referring to FIG. 15, in the array substrate 1, at least one (e.g., each) sub-pixel region 120 is provided with a plurality of slits 160 (e.g., three slits 160). Straight portions 163 of the plurality of slits 160 are parallel to each other, and first end portions 161 of the plurality of slits 160 are located on a same side of respective straight portions 163 connected to the first end portions 161. For example, in FIG. 15, the first end portions 161 of the plurality of slits 160 are respectively located on upper ends of the respective straight portions 163 connected to the first end portions 161. Accordingly, second end portions 162 of the plurality of slits 160 are respectively located on lower ends of the respective straight portions 163 connected to the second end portions 162. Since the first end portion 161 and the second end portion 162 have different shapes, and generate different electric field strengths of electric fields, which have different degrees of reduction in the Trace mura, the distribution range of the Trace mura at the position corresponding to the first end portion 161 is different from the distribution range of the Trace mura at the position corresponding to the second end portion 162. Since the region except the straight portions 163 needs to be covered by the black matrix to avoid the visualization of the Trace mura, if some first end portions 161 in a sub-pixel region 120 are located on a side of respective straight portions 163 connected to these first end portions 161, and the rest of first end portions 161 are located on another side of respective straight portions 163 connected to the rest of first end portions 161, when an end of each of the straight portions 163 is covered by the black matrix, it is necessary to consider an influence of the distribution range of the Trace mura at the position corresponding to the first end portion 161 and the distribution range of the Trace mura at the position corresponding to the second end portion 162 on a coverage of the black matrix. However, of the plurality of slits 160 in the sub-pixel region 120, in a case where the first end portions 161 are located on the same side of the respective straight portions 163 connected to the first end portions 161, and accordingly, the second end portions 162 are located on another side of the respective straight portions 163 connected to the second end portions 162, when Trace mura in an edge region of the sub-pixel region 120 provided with the first end portions 161 or the second end portions 162 is covered by the black matrix, for the arrangement of the black matrix, only an influence of the distribution range of the Trace mura at the position corresponding to the first end portion 161 or the distribution range of the Trace mura at the position corresponding to the second end portion 162 on the coverage of the black matrix needs to be considered. Thus, influence factors of the shape of the black matrix are reduced, which is conducive to reducing the design difficulty and simplifying the design, thereby controlling the production cost.

For example, referring to FIG. 15, in at least one (e.g., each) sub-pixel region 120, connection positions of the first end portions 161 and the straight portions 163 of the plurality of slits 160 (e.g., the slits 160 having respective straight portions 163 that are parallel to each other in the sub-pixel region 120) are on a straight line. In the case where the first end portions 161 of the plurality of slits 160 are located on the same side of the respective straight portions 163 connected to the first end portions 161, when the Trace mura is covered by the black matrix, the black matrix needs to completely cover the Trace mura distributed in the extending direction of the straight portion 163 (i.e., the extending direction of the first edge of the straight portion 163), so as to prevent the visualization of the Trace mura from adversely affecting the display effect. In a case where the connection positions of the first end portions 161 and the straight portions 163 of the plurality of slits 160 in the same sub-pixel region 120 are not on a straight line, there is a representative slit 160 parallel to the extending direction of the straight portion 163. Compared with other slits in the sub-pixel region 120, a connection position of a first end portion 161 and a straight portion 163 of the representative slit 160 and a connection position of any second end portion 162 and the straight portion 163 in the sub-pixel region 120 have a minimum distance therebetween. Then, in the edge region of the sub-pixel region 120 provided with the first end portions 161, the coverage of the black matrix is determined by a distribution range of the Trace mura at a position corresponding to the first end portion 161 of the representative slit 160. In the edge region of the sub-pixel region 120 provided with the second end portions 162, the coverage of the black matrix is determined by a distribution range of the Trace mura at a position corresponding to the second end portion 162 whose connection position with the straight portion 163 has the minimum distance from the connection position of the first end portion 161 and the straight portion 163 of the representative slit 160. In the case where the connection positions of the first end portions 161 and the straight portion 163 of the plurality of slits 160 are not on the straight line, when the foregoing second end portion 162 and the first end portion 161 of the representative slit 160 are covered by the black matrix, the straight portion(s) 163 of other slit(s) 160 may also be partially covered, so that the black matrix has a large coverage of this sub-pixel region 120, which is not conducive to increasing the aperture ratio. However, the connection positions of the first end portions 161 and the straight portions 163 of the plurality of slits 160 are arranged on the straight line, which can not only reduce the influence factors of the black matrix design, but also avoid the reduction in aperture ratio.

For example, referring to FIG. 15, in the array substrate 1, in at least one (e.g., each) sub-pixel region 120, the first end portions 161 of the plurality of slits 160 (e.g., the slits 160 having respective straight portions 163 that are parallel to each other in the sub-pixel region 120) are bent toward a same side of the respective straight portions 163 connected to the first end portions 161. That is, the bending directions of the first end portions 161 are all clockwise or counterclockwise. The above arrangement enables more slits 160 to be disposed in the sub-pixel region without changing the width of the slit 160, so that a stronger electric field may be formed without increasing energy consumption, so as to shorten the time required for changing the arrangement state of the liquid crystal molecules, which has a shorter response time, thereby further improving the display effect. Moreover, compared with a case that the bending directions of the first end portions 161 in the sub-pixel region 120 are different, when the plurality of slits 160 in the sub-pixel region 120 are arranged as above, since the shapes of the first end portions 161 in the sub-pixel region 120 are the same, the electric field strengths at positions respectively corresponding to the first end portions 161 are equal, so that liquid crystal molecules at the positions respectively corresponding to the first end portions 161 have the same deflection degree. The first end portions 161 have the same bending direction, so that deflection directions of the liquid crystal molecules at the positions respectively corresponding to the first end portions 161 are also the same. Thus, the arrangement states of the liquid crystal molecules at the positions respectively corresponding to the first end portions 161 in the sub-pixel region 120 are uniform, so as to avoid adverse effects on the display effect caused by the disordered arrangement of the liquid crystal molecules due to different bending directions of the first end portions 161, which is conducive to the improvement of the display effect.

For example, referring to FIG. 14, in the array substrate 1, the plurality of slits 160 (e.g., the slits 160 having respective straight portions 163 that are parallel to each other in the sub-pixel region 120) in at least one (e.g., each) sub-pixel region 120 have the same shape. The same shape means that of any two slits 160 in the array substrate 1, the first end portions 161 have the same shape, the second end portions 162 have the same shape, and the straight portions 163 have the same shape, and any one of the plurality of slits 160 in the sub-pixel region 120 may obtain other slits 160 in the sub-pixel region 120 only through position transformation (such as translation, horizontal flip, vertical flip, rotation). If the shapes of the first end portion 161 and the second end portion 162 are different, the distribution range of the Trace mura caused by the first end portion 161 and the distribution range of the Trace mura caused by the second end portion 162 are also different. However, the shapes of the plurality of slits 160 in the sub-pixel region 120 are the same, so that the distribution range of the Trace mura at a corresponding position of each slit 160 is the same, and when the black matrix is designed to cover the Trace mura, the difficulty of designing the shape of the black matrix is reduced.

For example, referring to FIG. 15, the plurality of sub-pixel regions 120 are arranged in a plurality of rows, and a row direction (i.e., X direction in FIG. 15) is parallel to an arrangement direction of the plurality of slits 160 in the sub-pixel region 120. In sub-pixel regions 120 in a same row, connection positions of first end portions 161 and straight portions 163 of slits 160 are located on a straight line. In sub-pixel regions 120 in a same column, first end portions 161 and the second end portions 162 of slits 160 are alternately arranged in a column direction. Similar to the above, in the sub-pixel regions 120 in the same row, the connection positions of the first end portions 161 and the straight portions 163 of the slits 160 are located on the straight line, so that the distribution range of the Trace mura at the position corresponding to the first end portion 161 of the representative slit 160 in the row, and the distribution range of the Trace mura at the position corresponding to the second end portion 162 in the same row whose connection position with the straight portion 163 has the minimum distance from the connection position of the first end portion 161 and the straight portion 163 of the representative slit 160 are determined, so as to determine the coverage of the black matrix in the edge region of the sub-pixel region 120 provided with the first end portions 161 and the coverage of the black matrix in the edge region of the sub-pixel region 120 provided with the second end portions 162 in the row. Therefore, in the embodiments of the present disclosure, the arrangement of slits 160 in the sub-pixel regions 120 in the same row can not only simplify the design, but also reduce the coverage of the black matrix to increase the aperture ratio of the sub-pixel region 120.

For example, referring to FIG. 15, in two adjacent sub-pixel regions 120 in a same row, first end portions 161 of slits 160 (e.g., slits 160 having respective straight portions 163 that are parallel to each other in the same row) are bent toward a same side of respective straight portions 163 connected to the first end portions 161 of the slits 160. That is, in sub-pixel regions 120 in the same row, the bending directions of the first end portions 161 of the slits 160 are the same. For example, referring to FIG. 15, in the sub-pixel regions 120 in the same row, the extending direction of the third edge of each of the first end portions 161 is clockwise or counterclockwise. Similar to the bending direction of each first end portion 161 in the sub-pixel region 120, this arrangement enables more slits 160 to be disposed in the sub-pixel regions 120 in the same row without changing the width of the slit 160, so that a stronger electric field may be formed without increasing energy consumption, so as to shorten the time required for changing the arrangement state of the liquid crystal molecules, which has a shorter response time, thereby further improving the display effect. In a case where the slits 160 in the sub-pixel regions 120 in the same row are arranged as above, similar to the case that the bending directions of the first end portions 161 in the sub-pixel region 120 are the same, the arrangement states of the liquid crystal molecules at the positions respectively corresponding to the first end portions 161 in the row are uniform, so as to avoid the adverse effects on the display effect caused by the disordered arrangement of the liquid crystal molecules due to different bending directions of the first end portions 161, which is conducive to the improvement of the display effect. In addition, in sub-pixel regions 120 in two adjacent rows, bending directions of first end portions 161 in a row may be the same as or different from bending directions of first end portions 161 in another row, which is not excessively limited.

For example, referring to FIG. 15, the plurality of sub-pixel regions 120 are arranged in a plurality of columns, and the column direction (i.e., Y direction in FIG. 15) is perpendicular to the arrangement direction of the plurality of slits 160 in the sub-pixel region 120 (e.g., slits 160 having respective straight portions 163 that are parallel to each other in a same row). In two adjacent sub-pixel regions 120 in a same column, first end portions 161 of a plurality of slits 160 in a sub-pixel region 120 are respectively close to second end portions 162 of a plurality of slits 160 in another sub-pixel region 120. In a case where second end portions 162 are concentratedly distributed on two sides of a second signal line 180, the Trace mura at positions respectively corresponding to the second end portions 162 is also concentratedly distributed. Since the shapes of the first end portion 161 and the second end portion 162 are different, and accordingly, a degree of the visualization of the Trace mura at the position corresponding to the first end portion 161 is different from a degree of the visualization of the Trace mura at the position corresponding to the second end portion 162. If the Trace mura at the positions respectively corresponding to the second end portions 162 is also concentratedly distributed, a probability that a user feels a difference in the distribution of the Trace mura is increased, so that a risk of visualization of the Trace mura is increased. However, through the above arrangement, the first end portions 161 and the second end portions 162 may be arranged alternately in the column direction, so that the Trace mura caused by the second end portions 162 from being concentratedly distributed on the sides of the second signal line 180, thereby achieving a more uniform display effect and reducing the risk of the visualization of the Trace mura.

For example, referring to FIG. 15, in two adjacent sub-pixel regions 120 in a same column, a straight line where each of first edges 1631 of a plurality of slits 160 in a sub-pixel region 120 is located is obtained by rotating the column direction clockwise by an acute angle, and a straight line where each of first edges 1631 of a plurality of slits 160 in another sub-pixel region 120 is located is obtained by rotating the column direction counterclockwise by an acute angle. One of the two adjacent sub-pixel regions 120 in the same column is a first sub-pixel region, and another one of the two adjacent sub-pixel regions 120 in the same column is a second sub-pixel region. A straight line where each of first edges 1631 of a plurality of slits 160 in the first sub-pixel region is located is obtained by rotating the column direction clockwise by an acute angle, and this acute angle is a first acute angle. A straight line where each of first edges 1631 of a plurality of slits 160 in the second sub-pixel region is located is obtained by rotating the column direction counterclockwise by an acute angle, and this acute angle is a second acute angle. Angle values of the first acute angle and the second acute angle may be equal or may not be equal, which is not excessively limited. In this case, the first edge of the straight portion 163 of the slit 160 in the first sub-pixel region and the first edge of the straight portion 163 of the slit 160 in the second sub-pixel region have different extending directions, and generate different directions of horizontal electric fields, so that the liquid crystal molecule in the first sub-pixel region and the liquid crystal molecule in the second sub-pixel region have different orientations, which is equivalent to having more display domains to make the orientations of the liquid crystal molecules more diverse during display, thereby effectively reducing color shift.

For example, referring to FIG. 15, the array substrate 1 further includes a plurality of first signal lines 170 and a plurality of second signal lines 180. The plurality of first signal lines 170 and the plurality of second signal lines 180 are configured to define the plurality of sub-pixel regions 120. Two adjacent first signal lines 170 and two adjacent second signal lines 180 define a sub-pixel region 120. In addition, the shapes of the first signal line 170 and the second signal line 180 are not excessively limited, and the first signal line 170 and the second signal line 180 may be straight lines or bend lines.

For example, referring to FIG. 15 again, in at least one (e.g., each) sub-pixel region 120, the first edges 1631 of the straight portions 163 of the plurality of slits 160 (e.g., slits 160 having respective straight portions 163 that are parallel to each other in each sub-pixel region 120) are parallel to a portion of a first signal line 170 for defining this sub-pixel region 120. This arrangement is conducive to maximizing the number of slits 160 that may be disposed in a single sub-pixel region 120, thereby forming a stronger electric field, so as to shorten the time required for changing the arrangement state of the liquid crystal molecules.

For example, referring to FIG. 15 again, the second signal line 180 is a straight line. At least one (e.g., each) first signal line 170 includes a plurality of first line segments 171 and a plurality of second line segments 172 that are alternately arranged, and extending directions of the first line segment 171 and the second line segment 172 are different. Any first line segment 171 and any second line segment 172 adjacent thereto in the first signal line 170 are axisymmetric about a second signal line 180 disposed between the first line segment 171 and the second line segment 172. That is, the first signal line 170 is a bend line, the second signal line 180 is the straight line, and each sub-pixel region 120 is defined by two second signal lines 180 and two first line segments 171 or by two second signal lines 180 and two second line segments 172. Two adjacent sub-pixel regions 120 coupled to a same first signal line 170 are respectively coupled to a first line segment 171 and a second line segment 172, and the first line segment 171 and the second line segment 172 are provided with a second signal 180 therebetween, and are axisymmetric about this second signal line 180. The first edge 1631 of the straight portion 163 of the slit 160 is parallel to the portion of the first signal line 170 for defining the sub-pixel region 120. Accordingly, one of two adjacent rows of sub-pixel regions 120 is defined as a first row, and another one of the two adjacent rows of sub-pixel regions 120 is defined as a second row. Therefore, extending directions of straight portions 163 that are respectively parallel to a portion of the first line segment 171 in the first row and a portion of the second line segment 172 in the second row are also axisymmetric about the second signal line 180. In the two adjacent rows of sub-pixel regions 120, an extending direction of a straight portion 163 in a sub-pixel region 120 in the first row is parallel to the portion of the first line segment 171 coupled to the sub-pixel region 120. That is, a straight line where each of first edges 1631 of slits 160 in the first row is located is obtained by rotating the column direction counterclockwise by an acute angle, and this acute angle is the first acute angle. An extending direction of a straight portion 163 in a sub-pixel region 120 in the second row is parallel to the portion of the second line segment 172 coupled to this sub-pixel region 120. That is, a straight line where each of first edges 1631 of slits 160 in the second row is located is obtained by rotating the column direction clockwise by an acute angle, and this acute angle is the second acute angle. The angle values of the first acute angle and the second acute angle are equal. According to the above arrangements, directions of electric fields generated by straight portions 163 in a row of sub-pixel regions 120 are different from directions of electric fields generated by straight portions 163 in an adjacent row of sub-pixel regions 120, so that the liquid crystal molecules have more diverse orientations during display, thereby effectively reducing the color shift. In addition, the extending directions of the straight portions 163 respectively located in two adjacent rows of sub-pixel regions 120 are axisymmetric about the second signal line 180, so that inclination directions of liquid crystal molecules respectively corresponding to the two adjacent rows of sub-pixel regions 120 are also axisymmetric about the second signal line 180. The symmetrical inclination directions enable the color shift in a viewing direction to cancel each other out, thereby further improving the display effect.

For example, referring to FIG. 15, the first signal line 170 is a gate line GL configured to transmit a gate driving signal, and the second signal line 180 is a data line DL configured to transmit a data signal. For another example, the first signal line 170 is a data line DL, and the second signal line 180 is a gate line GL. The gate driving signal may be provided from a gate scan driver (not shown in the figures), and the data signal may be provided from an integrated circuit (IC). Compared with a case that the extending direction of the straight portion 163 of the slit 160 is parallel to the gate line GL, when the extending direction of the straight portion 163 of the slit 160 is parallel to the data line DL, the first electrode 130 and the second electrode 140 in the sub-pixel region 120 have a smaller overlapping area and a smaller capacitance. Accordingly, a lower voltage output from the integrated circuit may charge a capacitor composed of the first electrode 130 and the second electrode 140. That is, the requirements for related hardwares are low, which is conducive to controlling the production cost. In addition, when the extending direction of the straight portion 163 of the slit 160 is parallel to the data line DL, the black matrix has a smaller coverage, and the black matrix may have a larger opening, thereby achieving a larger aperture ratio, which is conducive to improving the display effect.

For example, referring to FIGS. 9 and 13, an included angle (i.e., the bending angle α) between an extending line of the straight line LL where the connection position of the first end portion 161 and the straight portion 163 is located and the third edge 1611 is in a range of 40° to 60°, inclusive. The shape of the fifth edge 1613 is the broken line, and a length of each broken line segment in the fifth edge 1613 is 1 μm. A broken line segment in the broken line segments connected to the third edge 1611 is perpendicular to the straight line LL where the connection position of the first end portion 161 and the straight portion 163 is located. A broken line segment in the broken line segments connected to the fourth edge 1612 is parallel to the straight line LL where the connection position of the first end portion 161 and the straight portion 163 is located. Moreover, a distance between the broken line segment in the broken line segments connected to the fourth edge 1612 and the straight line where the connection position of the first end portion 161 and the straight portion 163 is located is in a range of 3 to 4.5 μm, inclusive. The shape of the second end portion 162 protruding in the extending direction of the straight portion 163 is the parallelogram. In FIG. 9, the included angle between the straight line LL where the connection position of the first end portion 161 and the straight portion 163 is located and the third edge 1611 is 40°. The distance h between the broken line segment in the broken line segments connected to the fourth edge 1612 and the straight line LL where the connection position of the first end portion 161 and the straight portion 163 is located is 3 μm. That is, a maximum depth of the first end portion 161 is 3 μm.

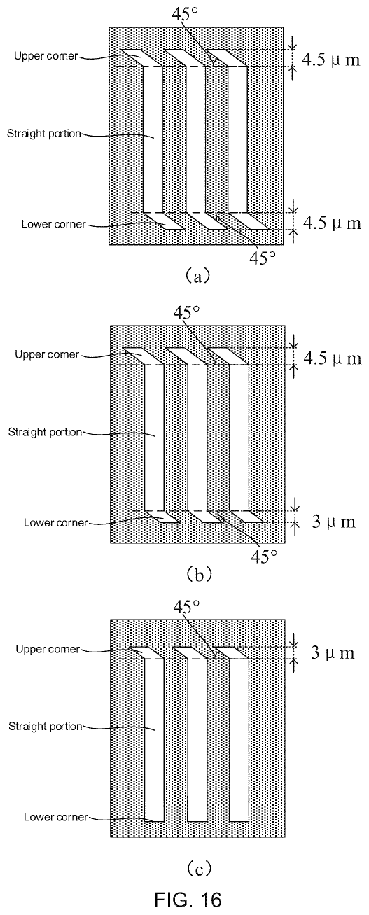

As shown in Table 1 below, the first electrode 130 is the pixel electrode, and the second electrode 140 is the common electrode. The shapes of the first end portion 161 and the second end portion 162 are set as shown in FIG. 9. A covering depth of the black matrix to the first end portion 161 is set to be equal to the maximum depth of the first end portion 161, which is 3 μm, so that when the pressing of the external force does not exist, the Trace mura at the position corresponding to the first end portion 161 is invisible. Similarly, the second end portion 162 is arranged to be covered by the black matrix, until the Trace mura at the position corresponding to the second end portion 162 is invisible when the pressing of the external force does not exist. In this case, a covering depth of the black matrix to the second end portion 162 is 2 μm. An arrangement of the pixel electrode and the common electrode in the related art is used as a contrast. Referring to (a) of FIG. 16, in the related art-1, the pixel electrode is a plate electrode (not shown in the figures), and the common electrode includes a plurality of electrode strips. A slit formed between two adjacent electrode strips in the common electrode is in a shape of crab legs. That is, two ends of a straight portion are sharpened to form an upper corner and a lower corner. There is a bending angle of 45° at a connection position of each of the upper corner and the lower corner and the straight portion, and the two corners each have a depth of 4.5 μm. A covering depth of a black matrix to each of the two corners is 4.5 μm (not shown in the figures). Referring to (b) of FIG. 16, in the related art-2, the pixel electrode is a plate electrode (not shown in the figures), and the common electrode includes a plurality of electrode strips. A slit formed between two adjacent electrode strips in the common electrode is in a shape of crab legs. There is a bending angle of 45° at a connection position of each of an upper corner and a lower corner and a straight portion, a depth of the upper corner is 4.5 μm, and a depth of the lower corner is 3 μm. A covering depth of a black matrix to each of the two corners is 3 μm (not shown in the figures). Referring to (c) of FIG. 16, in the related art-3, the pixel electrode is a plate electrode (not shown in the figures), and the common electrode includes a plurality of electrode strips. A slit is formed between two adjacent electrode strips in the common electrode. There is a bending angle of 45° at a connection position of an upper corner of the slit and a straight portion, and a lower corner of the slit is formed by the protrusion of the straight portion. A shape of the lower corer is a parallelogram, and a depth of the upper corner is 3 μm. The shape of the lower corner is the same as that of the straight portion, and is connected to the straight portion, which may be considered that the depth of the lower corner is 0 μm. A covering depth of a black matrix to each of the two corners is 3 μm (not shown in the figures). The same external force is applied to the liquid crystal display devices with the above different electrode structures to perform simulate pressing, and after pressing, the time required for the liquid crystal molecules in each of the liquid crystal display devices to restore an original arrangement is tested. The data obtained from the simulation are shown in Table 4 below.

TABLE 1
Simulation test results for different electrode arrangements

| | bending | | | bending | | Covering | Covering | | Recovery |
|---|---|---|---|---|---|---|---|---|---|
| | angle of | Depth of | | angle of | Depth | depth of | depth of | | duration |
| | upper | upper | | lower | of lower | upper | lower | Trace | after |
| | corner | corner | | corner | corner | corner | corner | mura | pressing |
| Related art-1 | 45° | 4.5 | μm | 45° | 4.5 μm | 4.5 μm | 4.5 μm | None | 14.5 ms |
| Related art-2 | 45° | 4.5 | μm | 45° | 3 μm | 3 μm | 3 μm | Small | 14.9 ms |
| | | | | | | | | amount | |
| Related art-3 | 40° | 3 | μm | 0° | 0 μm | 3 μm | 0 μm | Exist | 15.5 ms |
| Embodiments of | | | | | | | | | |
| the present | 40° | 3 | μm | 0° | 0 μm | 3 μm | 2 μm | None | 14.3 ms |
| disclosure | | | | | | | | | |

It can be seen that in a case where the electrode shape is set according to the shapes of the first end portion 161 and the second end portion 162 in the present disclosure, not only visible Trace mura does not exist, but also after pressing, the time required for liquid crystal molecules at a pressing position to return to the initial arrangement is shorter than that of the related art. Moreover, compared with the related art, the covering depth of the black matrix to each of the two corners in the solution of the present disclosure is not greater than the covering depth of the black matrix in the related art. After simulation, it is found that the electrode shape in the present disclosure enables the transmittance of the sub-pixel region to be increased by about 6.9% (the aperture ratio is increased by about 4.4%, and the liquid crystal light efficiency is increased by about 2.5%), so as to achieve a better display effect.

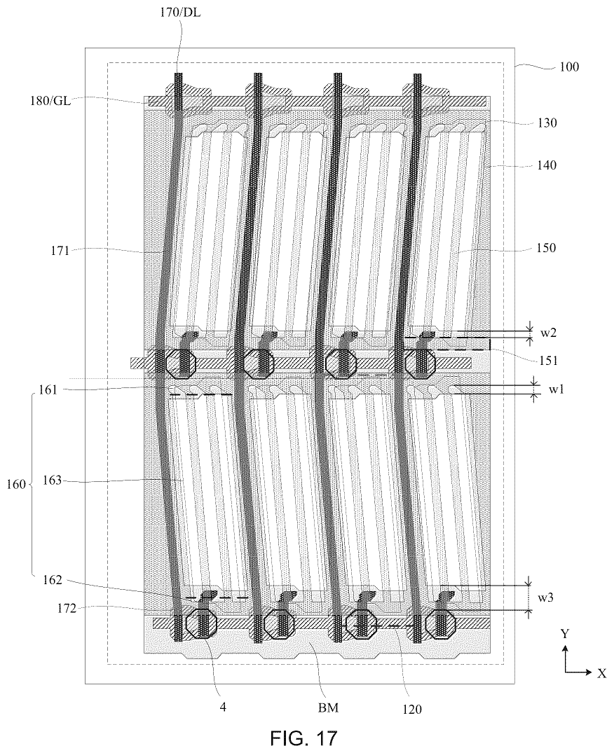

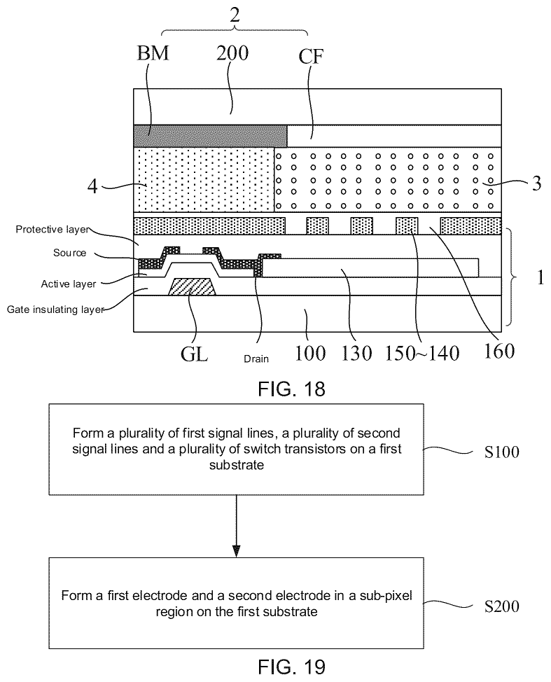

In a case where the array substrate 1 in the display assembly is arranged in any of the above ways, the black matrix in the display assembly may be set according to the following description. For example, referring to FIGS. 17 and 18, the black matrix BM is disposed on a side of the first electrode 130 and the second electrode 140 in the array substrate 1 away from the first substrate 100. An orthographic projection of the black matrix BM on the first substrate 100 covers at least a portion of an orthographic projection of the first end portion 161 included in the slit 160 in the array substrate on the first substrate 100, and covers an orthographic projection of the second end portion 162 included in the slit 160 on the first substrate 100. As described above, the black matrix BM needs to cover the region except the straight portions 163 to prevent the visualization of the Trace mura from adversely affecting the display effect, thereby avoiding the adverse effects on the display effect. Similar to a boundary line between the second end portion 162 and the straight portion 163, there is the bend at the connection position of the first end portion 161 and the straight portion 163, and the straight line where the connection position of the first end portion 161 and the straight portion 163 is located is a boundary line between the first end portion 161 and the straight portion 163. A distance from a point on an edge of the first end portion 161 to the boundary line between the first end portion 161 and the straight portion 163 is the depth of the first end portion 161, and there are a plurality of depth values of the first end portion 161. A distance w1 between an orthographic projection of an edge of the black matrix BM on the first substrate 100 and an orthographic projection of the edge of the first end portion 161 on the first substrate 100 is not less than the depth of the first end portion 161. That is, the orthographic projection of the black matrix BM on the first substrate 100 needs to at least completely cover an orthographic projection of each first end portion 161 on the first substrate 100, and the coverage range of the black matrix BM may be greater than a range of the first end portion 161, so as to cover the region except the straight portions 163 to prevent the visualization of the Trace mura from adversely affecting the display effect. Moreover, the expanded distribution range of the Trace mura caused by the pressing of the external force may be covered to further improve the display effect.

For example, in a case where the sixth edge 1621 and the seventh edge 1622 of the second end portion 162 are not parallel to each other, the shape of the second end portion 162 protruding from the straight portion 163 is not the parallelogram, so that the second end portion 162 and the straight portion are able to be clearly divided, and the straight line where the connection position of the second end portion 162 and the straight portion 163 is located is the boundary line between the second end portion 162 and the straight portion 163. In a case where the sixth edge 1621 and the first edge 1631 are on the same straight line, and the seventh edge 1622 and the second edge 1632 are on the same straight line, the sixth edge 1621 and the seventh edge 1622 are parallel to each other, and the eighth edge 1623 connected to the sixth edge 1621 and the seventh edge 1622 is a straight line. The shape of the second end portion 162 protruding from the straight portion 163 is the parallelogram. In this case, a portion, covered by the black matrix BM, of an end of the straight portion 163 away from the first end portion 161 is the second end portion 162.

For example, referring to FIG. 17, the orthographic projection of the black matrix BM on the first substrate 100 covers the orthographic projection of the first end portion 161 included in the slit 160 in the array substrate on the first substrate 100, and a portion of an edge of the black matrix BM is flush with the boundary line between the first end portion 161 and the straight portion 163 of each of at least one slit 160. The portion of the edge of the black matrix BM is flush with the boundary line between the first end portion 161 and the straight portion 163 of each of the at least one slit 160. That is, the distance w1 between the orthographic projection of the edge of the black matrix BM on the first substrate 100 and the orthographic projection of the edge of the end portion 161 on the first substrate 100 is equal to the depth of the first end portion 161. At the connection position of the first end portion 161 and the straight portion 163, this arrangement is able to make the black matrix BM only cover the position corresponding to the first end portion 161, so as to avoid covering the position corresponding to the straight portion 163, which is conducive to increasing the aperture ratio under a premise of avoiding the visualization of the Trace mura.

For example, referring to FIG. 17, the covering depth of the black matrix BM to one (e.g., each) second end portion 162 is not less than 2 μm. In a case where the shape of the second end portion 162 protruding from the straight portion 163 is not the parallelogram, a distance from a point on an edge of the second end portion 162 to the boundary line between the straight portion 163 and the second end portion 162 is the depth of the second end portion 162, and there are a plurality of depth values of the second end portion 162. The covering depth of the black matrix BM to the second end portion 162 is not less than the depth of the second end portion 162, and the covering depth is not less than 2 μm. In a case where the shape of the second end portion 162 protruding from the straight portion 163 is the parallelogram, a distance w2 between the orthographic projection of the edge of the black matrix BM on the first substrate 100 and an orthographic projection of the eighth edge 1623 of the second end portion 162 on the first substrate is not less than 2 μm. For example, a maximum distance w2 between the orthographic projection of the edge of the black matrix BM on the first substrate 100 and an orthographic projection of the edge of the second end portion 162 on the first substrate 100 is equal to 2 μm. Similar to the above, this arrangement may also cover the region except the straight portions 163 to prevent the visualization of the Trace mura from adversely affecting the display effect. Moreover, the visualization of the expanded distribution range of the Trace mura caused by the pressing of the external force is avoided.

In a case where the maximum distance w2 between the orthographic projection of the edge of the black matrix BM on the first substrate 100 and the orthographic projection of the edge of the second end portion 162 on the first substrate 100 is equal to 2 μm, the shape of the first end portion 161 is as shown in FIG. 9, and a maximum distance w1 between the orthographic projection of the edge of the black matrix BM on the first substrate 100 and the orthographic projection of the edge of the first end portion 161 on the first substrate 100 is equal to the depth of the first end portion 161, as described above, the aperture ratio is increased, and the display effect is greatly improved.

Referring to FIGS. 17 and 18, the liquid crystal layer 3 in the display assembly is disposed on the side of the first electrode 130 and the second electrode 140 away from the first substrate 100. In order to maintain the thickness of the liquid crystal layer 3 to realize normal display, the display assembly further includes at least one spacer 4 (e.g., a plurality of spacers 4). The spacer(s) 4 are also disposed on the side of the first electrode 130 and the second electrode 140 away from the first substrate 100, and are dispersed in the liquid crystal layer 3. A shape of the spacer 4 is not excessively limited, and may be a sphere, a cylinder, a circular truncated cone or a trustum of a pyramid.

Referring to FIGS. 17 and 18, the orthographic projection of the black matrix BM on the first substrate 100 completely covers an orthographic projection of at least one (e.g., each) spacer 4 on the first substrate 100. If the shape of the spacer 4 is the sphere, the shape of the orthographic projection of the spacer 4 on the first substrate 100 is a circle. If the shape of the spacer 4 is the cylinder, the shape and the size of the orthographic projection of the spacer 4 on the first substrate 100 are respectively the same as the shape and the size of each of an upper surface and a lower surface of the cylinder. If the shape of the spacer 4 is the circular truncated cone or the trustum of a pyramid, the shape and the size of the orthographic projection of the spacer 4 on the first substrate 100 are respectively the same as the shape and the size of one of an upper surface and a lower surface of the spacer 4 having a larger area. For example, referring to FIG. 17, a distance w3 between the orthographic projection of the edge of the black matrix BM on the first substrate 100 and an edge of the orthographic projection of the spacer 4 on the first substrate 100 is not less than 6 μm. For example, the shape of the spacer 4 is the trustum of a pyramid, a distance between orthographic projections of edges of the upper surface and the lower surface of the spacer 4 on the first substrate 100 is in a range of 4 μm to 7 μm, inclusive. A distance w3 between the orthographic projection of the edge of the black matrix BM on the first substrate 100 and an edge of an orthographic projection of the lower surface of the spacer 4 on the first substrate 100 is 6 μm. The presence of the spacer 4 makes of liquid crystal molecules in a certain region around the spacer 4 have disordered orientations, which results in light leakage of the peripheral region of the spacer 4, thereby affecting the display effect. Therefore, the black matrix BM covers the spacer 4 and the peripheral region thereof, thereby visually eliminating adverse effects of the light leakage on the display effect.

The above only illustrates the relative size of the black matrix BM and the spacer 4 in an example where the shape of the spacer 4 is the cylinder, and the shape of each of the upper surface and the lower surface of the spacer 4 is a regular octagon. It will be understood that in a case where the spacer 4 is in other shape, the black matrix BM and the spacer 4 are also arranged in the above manner.

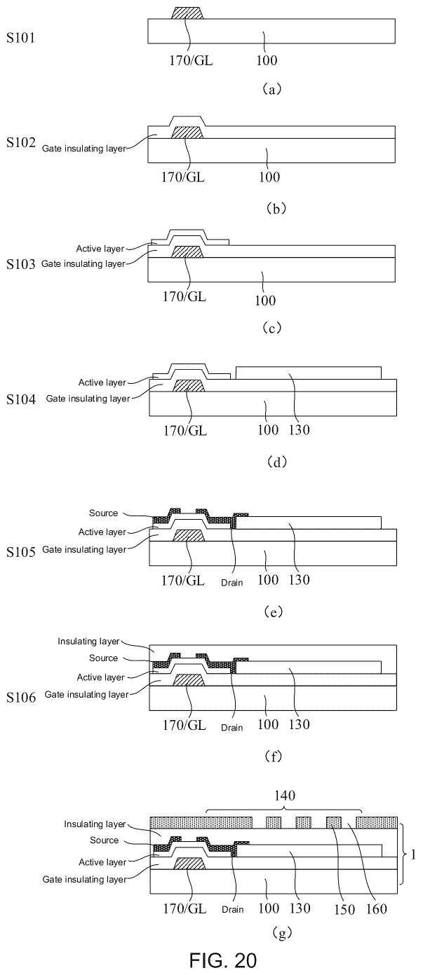

Some other embodiments of the present disclosure provide a manufacturing method of an array substrate, which may be used for manufacturing the array substrate in any one of the above embodiments. Referring to FIGS. 19 and 20, the manufacturing method of the array substrate 1 includes: S200, forming a first electrode 130 and a second electrode 140 in a sub-pixel region on a first substrate 100. At least one of the first electrode 130 and the second electrode 140 includes a plurality of electrode strips 150 parallel to each other. In the first electrode 130 and the second electrode 140, every two adjacent electrode strips 150 have a slit 160 therebetween. The slit 160 includes a first end portion, a straight portion and a second end portion connected in sequence. A bend is formed at a connection position of the first end portion and the straight portion. The second end portion is formed by protruding from the straight portion in an extending thereof. The straight portion includes a first edge and a second edge parallel to each other. An average width of the first end portion in a direction perpendicular to the first edge is less than a width of the straight portion.

For example, the first electrode 130 and the second electrode 140 may be arranged in the same layer, and are made of the same material. That is, the first electrode 130 and the second electrode 140 belong to the same pattern layer, which means that the first electrode 130 and the second electrode 140 may be formed through the same patterning process in this case. In the embodiments of the present disclosure, a plurality of patterns are formed through the same patterning process. The patterning process refers to a process capable of synchronously forming the plurality of patterns on a carrying surface. The patterning process may include: forming a film by using a film forming process, and then patterning the film to form a pattern layer including the plurality of patterns. The patterning process may include photoresist coating, exposure, development and etching processes. It will be noted that at least some of the plurality of patterns may be connected, or spaced apart from each other. In addition, the plurality of patterns may have different thicknesses (also referred to as heights).

For another example, the first electrode 130 and the second electrode 140 may be arranged in different layers, and in this case, the first electrode 130 and the second electrode 140 belong to different pattern layers.

The first electrode 130 may be made of indium tin oxide (ITO), indium zinc oxide (IZO), indium gallium oxide (IGO), gallium zinc oxide (GZO), zinc oxide (ZnO), indium oxide (In₂O₃), oxide aluminum zinc (AZO) or carbon nanotubes. A material that may be selected for the second electrode 140 is the same as that of the first electrode 130, and will not be repeated here.

Referring to FIGS. 19 and 20, the manufacturing method of the array substrate 1 further includes: S100, forming a plurality of first signal lines 170, a plurality of second signal lines 180 and a plurality of switch transistors on the first substrate 100.

The plurality of first signal lines 170 are parallel to each other, and the plurality of second signal lines 180 are parallel to each other. Each first signal line 170 cross the second signal lines 180 in space. The plurality of first signal lines 170 and the plurality of second signal lines 180 define a plurality of sub-pixel regions. For example, the first signal line is a gate line GL, and the second signal line is a data line DL.

As an example, S100 may be completed before S200. It is also possible that in S100, some patterns (such as the first signal lines) are completed before 200, and some other patterns (such as the second signal lines) are completed after the first electrode is formed and before the second electrode is formed.

All relevant content of the steps involved in the manufacturing method of the array substrate in the embodiments of the present disclosure may refer to the corresponding description of the corresponding array substrate, and the manufacturing method of the array substrate in the embodiments of the present disclosure is also able to achieve the same beneficial effects as the array substrate in any one of the above embodiments, which will not be repeated here.

The manufacturing method of the array substrate will be described in detail below in an example where the array substrate 1 shown in FIG. 20 is manufactured (in the array substrate 1, the first electrode 130 is a plate electrode, the second electrode 140 includes a plurality of electrode strips 150, and the second electrode 140 is a common electrode disposed on a side of the first electrode 130 away from the first substrate 100).

For example, referring to FIG. 20, the manufacturing method of the array substrate 1 may include following steps.

In S101, a first pattern layer is formed on the first substrate 100.

Referring to (a) of FIG. 20, the first pattern layer includes the plurality of first signal lines 170 (i.e., gate lines GL). The step of forming the first pattern layer may include: forming a first conductive film on the first substrate 100, and patterning the first conductive film to form the first pattern layer including the plurality of first signal lines 170.

The first conductive film may be formed by any one of various film-forming processes such as deposition, coating and sputtering. Then, the first conductive film may be patterned to form the plurality of first signal lines 170 by photoresist coating, exposure, development, etching and photoresist peeling.

The first pattern layer may be made of at least one of metal, metal alloy, metal oxide conductive material. For example, the first pattern layer may be made of metal, and the first pattern layer is made of molybdenum (Mo).

In S102, a gate insulating layer is formed on the first substrate 100.

Referring to (b) of FIG. 20, the gate insulating layer is formed on the first substrate 100 on which the first pattern layer is formed.

A material of the gate insulating layer may be selected from silicon nitride or silicon oxide.

In S103, an active pattern layer is formed on the first substrate 100.

Referring to (c) of FIG. 20, the active pattern layer is formed on the first substrate 100 on which the gate insulating layer is formed. For example, a semiconductor film is formed on the first substrate 100 on which the gate insulating layer is formed, and is patterned to form the active pattern layer including a plurality of active layers. One of the active layers is a semiconductor pattern of a switch transistor.

The active pattern layer may be made of a-Si, or an oxide semiconductor.

In S104, a second pattern layer is formed on the first substrate 100.

Referring to (d) of FIG. 20, a conductive film is formed on the first substrate 100 on which the active pattern layer is formed, and is patterned to form the second pattern layer. The second pattern layer includes a plurality of first electrodes 130.

In S105, a third pattern layer is formed on the first substrate 100.

Referring to (e) of FIG. 20, the third pattern layer is located on a side of the second pattern layer away from the first substrate 100. The third pattern layer includes the plurality of second signal lines (i.e., data lines DL, not shown in the figures), a plurality of sources, and a plurality of drains. Each data line is coupled to sources, and each first electrode 130 is coupled to a drain. In this case, the first electrode 130 is a pixel electrode.

A material that may be selected for the third pattern layer is the same as that of the first pattern layer, and a formation method of the second signal lines is similar to that of the first signal lines 170, which will not be repeated here.

In S106, a protective layer (also referred to as a passivation layer or a PVX layer) is formed on the first substrate 100.

Referring to (f) of FIG. 20, the protective layer is formed on the first substrate 100 on which the plurality of second signal lines, the plurality of sources and the plurality of drains are formed. After the protective layer is formed, the second electrodes 140 as described above are formed to obtain the array substrate as shown in (g) of FIG. 20.

The foregoing descriptions are merely some specific implementation manners of the present disclosure, but the protection scope of the present disclosure is not limited thereto. Changes or replacements that any person skilled in the art could conceive of within the technical scope of the present disclosure shall all be included in the protection scope of the present disclosure. Therefore, the protection scope of the present disclosure shall be subject to the protection scope of the claims.

1. An array substrate having a plurality of sub-pixel regions, the array substrate comprising:
a first substrate; and
a first electrode and a second electrode that are disposed on the first substrate and located in a sub-pixel region; wherein at least one of the first electrode and the second electrode includes a plurality of electrode strips; every two adjacent electrode strips in the first electrode and the second electrode have a slit therebetween; the slit includes a first end portion, a straight portion and a second end portion connected in sequence; a bend is formed at a connection position of the first end portion and the straight portion, and the second end portion is formed by protruding from the straight portion in an extending direction of the straight portion; wherein
the straight portion includes a first edge and a second edge parallel to each other, and an average width of the first end portion in a direction perpendicular to the first edge is less than a width of the straight portion.

2. The array substrate according to claim 1, wherein
a maximum width of the first end portion in the direction perpendicular to the first edge is less than the width of the straight portion.

3. The array substrate according to claim 1, wherein
the first end portion includes a third edge and a fourth edge that are parallel to each other and respectively connected to the first edge and the second edge of the straight portion, and a fifth edge connected to the third edge and the fourth edge; wherein an included angle between the third edge and the first edge is an obtuse angle;
and/or
the second end portion includes a sixth edge and a seventh edge; the sixth edge and the first edge are located on a same straight line, and the seventh edge and the second edge are located on a same straight line.

4. The array substrate according to claim 3, wherein
in the slit, the fifth edge of the first end portion is a convex curve or a convex broken line protruding in a direction away from the straight portion.

5. The array substrate according to claim 1, wherein
the sub-pixel region is provided with a plurality of slits therein; straight portions of the plurality of slits are parallel to each other, and first end portions of the plurality of slits are located on a same side of respective straight portions connected to the first end portions.

6. The array substrate according to claim 5, wherein
in the sub-pixel region, connection positions of the first end portions and the straight portions of the plurality of slits are on a straight line.

7. The array substrate according to claim 5, wherein
in the sub-pixel region, the first end portions of the plurality of slits are bent toward a same side of the respective straight portions connected to the first end portions.

8. The array substrate according to claim 7, wherein
the plurality of sub-pixel regions are arranged in a plurality of rows, and a row direction is parallel to an arrangement direction of the plurality of slits in the sub-pixel region; and
in two adjacent sub-pixel regions in a same row, first end portions of slits are bent toward a same side of respective straight portions connected to the first end portions of the slits in the two adjacent sub-pixel regions.

9. The array substrate according to claim 5, wherein
the plurality of sub-pixel regions are arranged in a plurality of columns, and a column direction is perpendicular to an arrangement direction of the plurality of slits in the sub-pixel region; and
in two adjacent sub-pixel regions in a same column, first end portions of a plurality of slits in a sub-pixel region are respectively close to second end portions of a plurality of slits in another sub-pixel region.

10. The array substrate according to claim 5, wherein
the plurality of sub-pixel regions are arranged in a plurality of columns, and a column direction is perpendicular to an arrangement direction of the plurality of slits in the sub-pixel region; and
in two adjacent sub-pixel regions in a same column, a straight line where first edges of a plurality of slits in a sub-pixel region are located is obtained by rotating the column direction clockwise by an acute angle, and a straight line where first edges of a plurality of slits in another sub-pixel region are located is obtained by rotating the column direction counterclockwise by an acute angle.

11. The array substrate according to claim 5, wherein the array substrate further comprises:
a plurality of first signal lines and a plurality of second signal lines configured to define the plurality of sub-pixel regions; wherein
in the sub-pixel region, first edges of the straight portions of the plurality of slits are parallel to a portion of a first signal line for defining the sub-pixel region.

12. The array substrate according to claim 11, wherein
the second signal lines are straight lines; and
the first signal line includes a plurality of first line segments and a plurality of second line segments that are alternately arranged, and an extending direction of a first line segment is different from an extending direction of a second line segment; any first line segment and any second line segment adjacent to the any first line segment in the first signal line are axisymmetric about a second signal line disposed between the any first line segment and the any second line segment.

13. The array substrate according to claim 11, wherein
the first signal lines are data lines, and the second signal lines are gate lines.

14. A display assembly, comprising:
the array substrate according to claim 1;
a black matrix disposed on a side of the first electrode and the second electrode in the array substrate away from the first substrate; wherein an orthographic projection of the black matrix on the first substrate covers at least a portion of an orthographic projection, on the first substrate, of the first end portion included in the slit in the array substrate, and covers an orthographic projection, on the first substrate, of the second end portion included in the slit.

15. The display assembly according to claim 14, wherein
the orthographic projection of the black matrix on the first substrate covers the orthographic projection, on the first substrate, of the first end portion included in the slit in the array substrate; and a portion of an edge of the black matrix is flush with a boundary line between a first end portion and a straight portion of each of at least one slit.

16. The display assembly according to claim 14, wherein
a covering depth of the black matrix to the second end portion is no less than 2 μm.

17. The display assembly according to claim 14, further comprising:
at least one spacer disposed on the side of the first electrode and the second electrode away from the first substrate; wherein
the orthographic projection of the black matrix on the first substrate covers an orthographic projection of a spacer in the at least one spacer on the first substrate.

18. The display assembly according to claim 17, wherein
a distance between an orthographic projection of an edge of the black matrix on the first substrate and an edge of the orthographic projection of the spacer on the first substrate is not less than 4 μm.

19. A display device, comprising the display assembly according to claim 14.

20. A manufacturing method of an array substrate, the array substrate having a plurality of sub-pixel regions, the manufacturing method of the array substrate comprising:
forming a first electrode and a second electrode that are located in a sub-pixel region on a first substrate; wherein at least one of the first electrode and the second electrode includes a plurality of electrode strips parallel to each other, and every two adjacent electrode strips in the first electrode and the second electrode have a slit therebetween; the slit includes a first end portion, a straight portion and a second end portion connected in sequence; a bend is formed at a connection position of the first end portion and the straight portion, and the second end portion is formed by protruding from the straight portion in an extending direction of the straight portion.
